(19) United States
(12) Patent Application Publication
(10) Pub. No.: US 2005/0128715 A1
(43) Pub. Date: Jun. 16, 2005

(54) Integrated-circuit cooling system

(75) Inventor: Ronen Betman, Yokneam Ilit (IL)

Correspondence Address: DR. MARK FRIEDMAN LTD.;c/o Bill Polkinghorn, 9003 Florin Way, Upper Marlboro, MD, 20772, US

(73) Assignee: RAFAEL - ARMAMENT DEVELOPMENT AUTHORITY LTD.

(21) Appl. No.: 11/008,938

(22) Filed: Dec. 13, 2004

(30) Foreign Application Priority Data
Dec. 16, 2003 (IL) 159399

(51) Int. Cl. H05K 7/20

(52) U.S. Cl. 361/719

(57) ABSTRACT

A system for cooling an IC using a cold plate heatsink employs at least one adjustable thermally-conductive extension segment extending therefrom. The system deploys an elastically compressible thermally-conductive shock absorbing pad between, and in contact with both, a contact face of the extension segment and a contact surface of an electrical component, such as an IC, so as to form a substantially physically-continuous thermally-conductive heat transfer mechanism while protecting the electrical component from being damaged by direct contact with the extension segment.

### FIELD AND BACKGROUND OF THE INVENTION

The present invention relates to the cooling of electronic components and, in particular, it concerns a system for the cooling of an integrated circuit (IC) using a cold plate heatsink.

One of the most popular methods utilized to dissipate heat from an IC is convection dissipation directly from the IC, especially via cooling fans in close proximity of the IC. In this method, the moving air carries thermal energy directly from the heated IC and dissipates it to the ambient atmosphere. While this is sufficient for many purposes, it has been found that fan cooling alone does not provide the needed cooling for many circumstances.

Another commonly utilized method of heat dissipation utilizes a combination of conduction and radiation. Devices known as “heatsinks” are adapted to mount in direct contact with the ICs such that the thermal energy may be conducted from the IC to the heatsink device. Most heatsinks are then provided with substantial surface area not in contact with the IC such that the conducted thermal energy can dissipate into the air. Many heatsink devices include heat dissipation fins of various configurations, while others rely principally on substantial mass to absorb the heat, especially transient heat.

Due to the fragility of ICs, various solutions as to how to configure the interface between the IC and the cooling system and control the pressure applied to the IC by the cooling system elements have been offered, and include ensuring direct contact allowing for no movement between the IC and the heatsink, and maintaining a small gap between the IC and the heatsink.

Prior art in the first category, ensuring direct contact, includes U.S. Pat. No. 5,932,925, JP 11251496, JP 62093965, JP 02291156 and JP 3266458. U.S. Pat. No. 5,932,925 discloses an adjustable pressure mount heatsink subassembly for use with electronic chip components. The system includes a heatsink portion associated with a mounting subassembly. The mounting subassembly includes a spring clip to ensure direct contact between the chip and the heatsink. JP11251496 describes gluing a bolt to the top of an IC so that a heatsink may be bolted to the IC. JP62093965 discloses the deployment of a conical coil spring between the IC and the heatsink. Both JP02291156 and JP3266458 describe different ways of mounting disengageable heatsinks to a third member in direct contact with the IC. Systems utilizing direct contact heatsinks suffer from the possibility that vibrations may cause impact of the conductive element on IC and may cause damage to the IC. This is true even with spring biased mechanisms.

Systems of prior art that leave a small gap between the IC and the cooling apparatus include U.S. Pat. No. 4,628,990 and JP 61049445. U.S. Pat. No. 4,628,990 discloses a cooling system having a cooling plate associated with conductive pistons. The pistons are adjusted and fixed in an assembly so that a desired gap is maintained between the pistons and the components, and no direct contact is made between the electronic components. JP 61049445 describes varying the length of bars inserted into a thermally conductive plate, to which a water jacket is attached, such that there is a gap between the top surface of the IC and the end of one of the bars. Systems of this type suffer from the disadvantage that the very large thermal impedance of the air in the gap, however small, greatly reduces cooling efficiency.

A further drawback to cooling systems that rely on fans is their inability to provide sufficient cooling for applications where there is no, or insufficient, air, or other gases, present to be blown by the fan. This would be the case for systems used in a vacuum, partial vacuum, or outside the Earth's atmosphere. Similarly, there are applications where space is limited and deployment of a fan is impossible.

There is therefore a need for a system for cooling an IC using a cold plate heatsink, such system configured so as to reduce thermal resistance by the use of adjustable thermally conductive extension segments, the system deploying an elastically compressible thermally-conductive shock-absorbing pad deployed between, and in contact with both, a contact face of the extension segment and a contact surface of the integrated circuit configured for substantially physically-continuous thermally-conductive heat transfer while protecting the IC from being damaged by direct contact with the extension segment.

### SUMMARY OF THE INVENTION

The present invention is a system for cooling an IC using a cold plate heatsink, such system configured so as to reduce thermal resistance by the use of adjustable thermally conductive extension segments, the system deploying an elastically compressible thermally-conductive shock-absorbing pad deployed between, and in contact with both, a contact face of the extension segment and a contact surface of the integrated circuit configured for substantially physically-continuous thermally-conductive heat transfer while protecting the IC from being damaged by direct contact with the extension segment.

According to the teachings of the present invention there is provided, a heat transfer system for cooling electrical components mounted on a mounting surface, the system comprising: (a) a heat dissipation element configured with at least one attachment opening, the attachment opening configured as a through bore; (b) a thermally-conductive extension segment inserted through, and in contact with at least one peripheral wall of, each the attachment opening and extending toward the electrical component, wherein an extension length of the extension segment toward the electrical component is variable so as to facilitate positioning of a contact face of the extension segment in relation to a contact surface of the electrical component; and (c) an elastically compressible thermally-conductive shock-absorbing pad deployed between, and contacting both, the contact face of the extension segment and the contact surface of the electrical component.

According to a further teaching of the present invention, there is also provided a thermally-conductive filler deployed in the attachment opening so as to enhance thermal conductivity between the heat dissipation element and the extension segment.

According to a further teaching of the present invention, the thermally-conductive filler includes a thermally-conductive adhesive.

According to a further teaching of the present invention, a distance between the contact face of the extension segment and the contact surface of the electrical component is in a range of between 0.1 mm-0.2 mm.

According to a further teaching of the present invention, at least a portion of the attachment opening is threaded.

According to a further teaching of the present invention, at least a portion of the extension segment is threaded so as to screw into the attachment opening, such that the extension length of the extension segment is varied by turning the extension segment.

There is also provided according to the teachings of the present invention, a heat transfer method for cooling an electrical component mounted on a mounting surface, the method comprising: (a) providing a heat dissipation element configured with at least one attachment opening, the attachment opening configured as a through bore; (b) inserting a thermally-conductive extension segment through each of the at least one attachment opening so as to contact at least one peripheral wall of the opening and extending toward the electrical component; (c) deploying an elastically compressible thermally-conductive shock-absorbing pad between a contact face of the extension segment and a contact surface of the electrical component; and (d) varying an extension length of the extension segment toward the electrical component so as to facilitate positioning of a contact face of the extension segment in relation to a contact surface of the electrical component, the elastically compressible thermally-conductive shock-absorbing pad deployed there between, and in contact with both.

According to a further teaching of the present invention, there is also provided deploying a thermally-conductive filler in the attachment opening so as to enhance thermal conductivity between the extension segment and the heat dissipation element.

According to a further teaching of the present invention, the thermally-conductive filler is implemented as a thermally-conductive adhesive.

According to a further teaching of the present invention, there is also provided varying the extension length of the extension segment such that a distance between the contact face of the extension segment and the contact surface of the electrical component is in a range of between 0.1 mm-0.2 mm.

According to a further teaching of the present invention, at least a portion of the attachment opening is implemented as a threaded opening.

According to a further teaching of the present invention, at least a portion of the extension segment is threaded so as to screw into the attachment opening.

According to a further teaching of the present invention, the varying of the extension length of the extension segment is accomplished by turning the extension segment.

### BRIEF DESCRIPTION OF THE DRAWINGS

The invention is herein described, by way of example only, with reference to the accompanying drawings, wherein:

FIG. 1 is schematic side cross-sectional view of a first preferred embodiment constructed and operable according to the teachings of the present invention shown here associated with an IC having a raised die section of its top surface;

FIG.2 is schematic side cross-sectional view of the embodiment of FIG. 1 shown here associated with an IC having a substantially planar top surface; and

FIGS. 3-5 are graphs illustrating the cooling effectiveness of various embodiments constructed and operable according to the teachings of the present invention.

### DESCRIPTION OF THE PREFERRED EMBODIMENTS

The present invention is a system for cooling an IC using a cold plate heatsink, such system configured so as to reduce thermal resistance by the use of adjustable thermally conductive extension segments, the system deploying an elastically compressible thermally-conductive shock-absorbing pad deployed between, and in contact with both, a contact face of the extension segment and a contact surface of the integrated circuit configured for substantially physically-continuous thermally-conductive heat transfer while protecting the IC from being damaged by direct contact with the extension segment.

The principles and operation of a system for cooling an IC using a cold plate heatsink according to the present invention may be better understood with reference to the drawings and the accompanying description.

By way of introduction, it will be appreciated that the principles of the present invention may be applied with equal benefit to a wide variety of electronic components and applications such as, but not limited to, integrated circuits (ICs), switches and motors. The cooling system described herein may be implemented, with equal benefit, in association with a full PC board mounting frame and cold plate or a locally mounted cold plate or cup, all of which are known in the art.

It is a principle of the present invention to lower the thermal resistance of the cooling system by providing a system configured for substantially physically-continuous thermally-conductive heat transfer so as to conduct heat away from the IC to the cold plate. As used herein, the term “thermally-conductive” refers to the transfer of heat at a rate higher that an equal volume of air at the same temperature as the material being used.

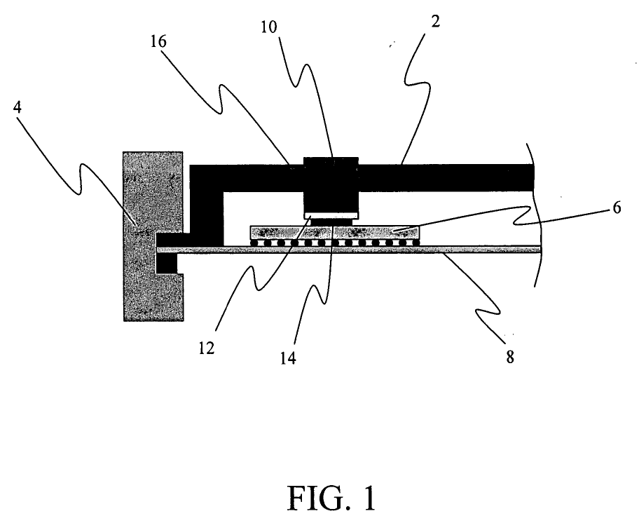

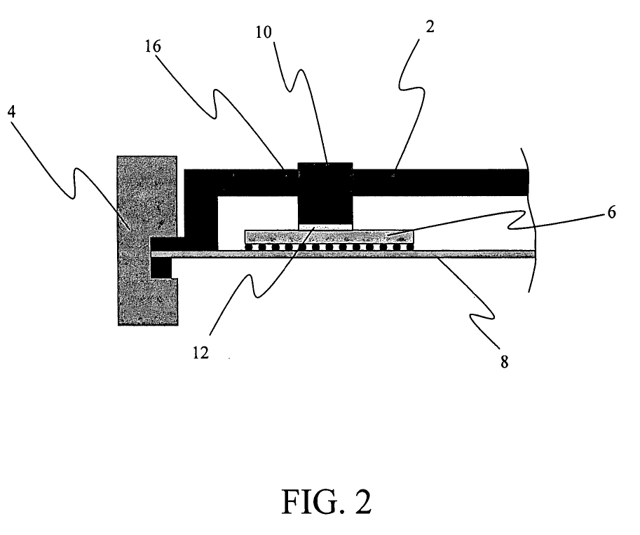

Referring now to the drawings, it should be noted that due to the similarity of FIGS. 1 and 2, corresponding elements of each figure are numbered the same. As illustrated in FIGS. 1 and 2, some ICs are configured with a raised die region 14 on the top surface which may affect the size of the contact surface between the shock-absorbing pad 12 and the IC 6 (FIG. 1), while other ICs do not have such a die region (FIG. 2). It should be noted that use of the cooling system of the present invention is equally beneficial with both types of ICs.

Preferably a cold plate 2, although substantially any heat dissipation element is with in the scope of the present invention, is deployed inside the cabinet (represented by cabinet wall section 4) containing the electrical components to be cooled. As illustrated here, an IC 6 is mounted on a PC board 8. The cold plate 2 has at least one attachment opening 16 that is configured as a through bore. A thermally-conductive extension segment 10 is inserted through the attachment opening 16 such that the extension segment 10 extends at least toward the IC 6 and may extend from the cold plate 2 in a direction away form the IC as well. Deployed between the surface of IC 6 and the surface of the extension segment 10 proximal thereto is a thin elastically compressible thermally-conductive shock-absorbing pad 12.

During installation of the cooling system on the PC board, the extension length of the extension segment 10 is varied in order to compress the shock-absorbing pad so as to achieve optimal thermal conduction. The optimal distance between the extension segment 10 and the IC 6, with the shock-absorbing pad 12 compressed there between, is in the range of between of 0.1 mm-0.2 mm, thereby being configured for substantially physically-continuous thermally-conductive heat transfer that includes the shock-absorbing pad 12. The extension segment 10 may be fixedly attached to the cold plate 2, preferably using a thermally-conductive filler such as, but not limited to, a thermally-conductive adhesive, such as but not limited to, Loctite 384®. Alternatively, the extension segment 10 may be fixedly attached to the cold plate 2 in some other manner known in the art. In this case, a non-adhesive filler may be used, or the filler may be omitted completely.

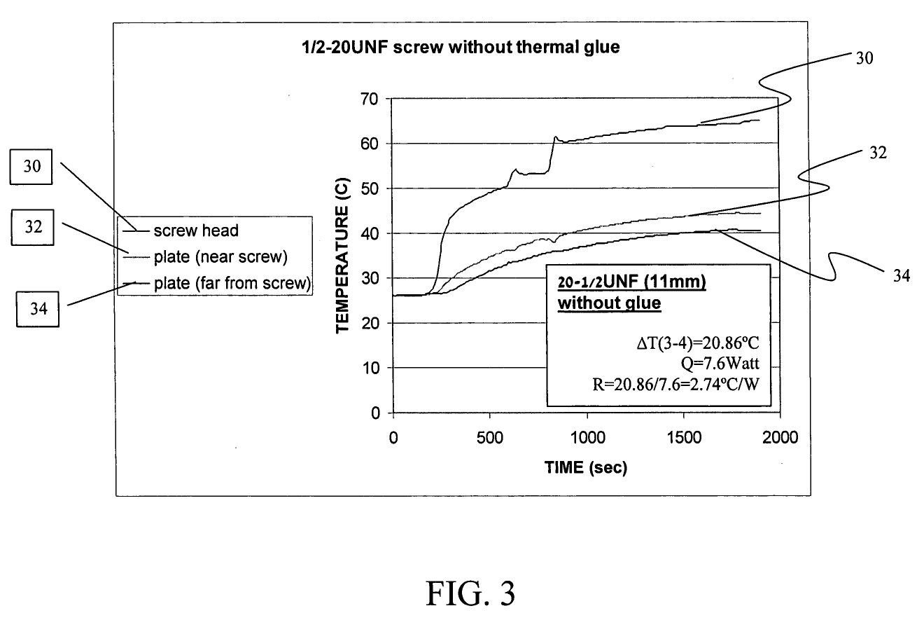

In some embodiments of the present invention, the extension segment 10 may be implemented as a threaded element that engages a threaded attachment opening 16, as in the embodiment used for the testing referenced below with regard to FIGS. 3-5. It will be appreciated that such an extension segment has a substantially circular cross-sectional outline. Configured in this manner, the length of the extension segment 10 may be adjusted by turning the extension segment 10 in an appropriate direction so as to shorten or lengthen its length of extension. Once the optimal distance between the extension segment 10 and the IC 6 is reached, thereby being configured for substantially physically-continuous thermally-conductive heat transfer that includes the shock-absorbing pad 12, the extension segment 10 may optionally be fixedly attached to the cold plate 2.

In an alternative embodiment of the present invention, the extension segment and the attachment opening are not threaded. In such an embodiment the extension segment 10 may have a cross-sectional outline of substantially any suitable closed figure, such as, but not limited to, a circle, an oval, a square, a triangle, or any other polygon, as long as the attachment opening 16 has a corresponding shape so as to facilitate surface contact between the sides of the extension segment 10 and the peripheral wall of the attachment opening 16. As the extension segment 10 is inserted through the attachment opening 16, the length of the extension segment 10 is varied until the distance between the contact face of the extension segment and the contact surface of the electrical component falls within an optimal range of between 0.1 mm-0.2 mm. Once the optimal distance between the extension segment 10 and the IC 6 is reached, thereby being configured for substantially physically-continuous thermally-conductive heat transfer that includes the shock-absorbing pad 12, the extension segment 10 may be fixedly attached to the cold plate 2, preferably using a thermally-conductive filler such as, but not limited to, a thermally-conductive adhesive, such as but not limited to, Loctite 384®. Alternatively, the extension segment may be fixedly held in place by friction or by substantially any appropriate attachment mechanism such as, but not limited to, bolts, clamps, shims, and wedges.

In any of the embodiments of the present invention, the shock-absorbing pad 12, preferably has an uncompressed thickness of between 0.2 mm-0.3 mm, although, the uncompressed thickness may be larger than 0.3 mm. The compressed thickness of the shock-absorbing pad is preferably between 0.1 mm-0.2 mm, but may be in the range of 0.1 mm-1.0 mm. A shock-absorbing pad with an uncompressed thickness greater than 1.0 mm would fall within the scope of the present invention. This optimal range is generally less than the thickness of the shock-absorbing pad 12; therefore, some compression of the shock-absorbing pad occurs. Compressing the shock-absorbing pad within the gap of 0.1 mm-0.2 mm lowers the thermal resistance of the elastically compressible material while protecting the IC from accidental damage that may be caused by unintentional contact with the extension segment itself.

It should be noted that preferably the system is designed should that the amount of pressure required to compress the pad 12 to its optimal thermal conductive state is less than the maximum pressure which the IC is able to withstand without being damaged. Therefore, when the extension segment 10 is implemented as a threaded element, torque is applied to the extension segment 10 until a predetermined value is reached, at which point the extension segment is fixed to the cold plate. In the embodiments discussed herein, the predetermined torque results in compression of the pad 12 to a thickness of 0.1 mm-0.2 mm. Both the force applied to the IC and the resulting thickness for the pad 12 may be varied, by design, dependent upon the physical limitations of the components being used and the particular conditions under which they are used. That is, the maximum pressure which the IC can withstand and, for example, the amount of vibration experienced by the system during use may allow the pad 12 to be compressed such that the gap is at the lower end of the 0.01 mm-0.2 mm range. Alternatively, these variables may require that the system be designed such that compression of the pad 12, and therefore the gap is larger than 0.2 mm, and up to 1.0 mm, for example.

The distance between the cold plate and the IC, and therefore the distance to which the extension segment may be extended from the cold plate in order to establish the gap of 0.1 mm-0.2 mm, is determined by the thermal conductive properties of the material from which the extension segment is fabricated and the amount of heat generated by the IC. The thermal resistance (R) of the extension segment is calculated using the formula R=l/ka, where l is the length of the extension segment, k is the thermal conductivity factor of the material from which the extension segment is fabricated and the cross-sectional area of the extension segment. The resulting figure may be expressed as degrees Celsius per watt. It will be readily appreciated that varying the dimensions of the extension segment has a direct affect on the cooling effectiveness of the system. This may be in the form of the distance that the extension segment extends from the cold plate, or in the cross-sectional area, or diameter, of the extension segment, as will be discussed in detail below with regard to FIGS. 3-5. The same formula may be applied to all of the elements of the cooling system, such as, but not limited to, the shock-absorbing pad, the extension segment, and the cold plate. Therefore, when the amount of heat generated by the IC and the thermal resistances of each of the system are known, the cooling effect of the system may be determined.

It will be appreciated that the cross-sectional area of the extension segment 10, as mentioned above, and the thermal conductivity of the interface of the extension segment 10 and the cold plate 2 will directly affect the cooling effectiveness of the cooling system of the present invention. Therefore, FIGS. 3-5 are provided to illustrate the cooling effectiveness of three representative configurations of the present invention.

FIG. 3 shows the cooling results using a ½-20 UNF screw as the extension segment 10. In this test, the screw was not fixedly attached to the cold plate, nor was any thermally conductive filler used. The temperature 30 of the extension segment (screw head) and the temperature 16 of the cold plate adjacent to attachment opening were tracked against time. As the graph shows, the extension segment 10 absorbed heat form the IC 2. However, due most probably to the poor thermal conductivity between the extension segment 10 and the cold plate 2, the temperature 30 of the extension segment 10 was approximately 20° C. hotter than the temperature 32 of the region of the cold plate 2 near the attachment opening after 1500 seconds. Further, the temperature 34 of a region removed from the attachment opening was less than 5° C. cooler than the temperature 32 of the region close to the attachment opening.

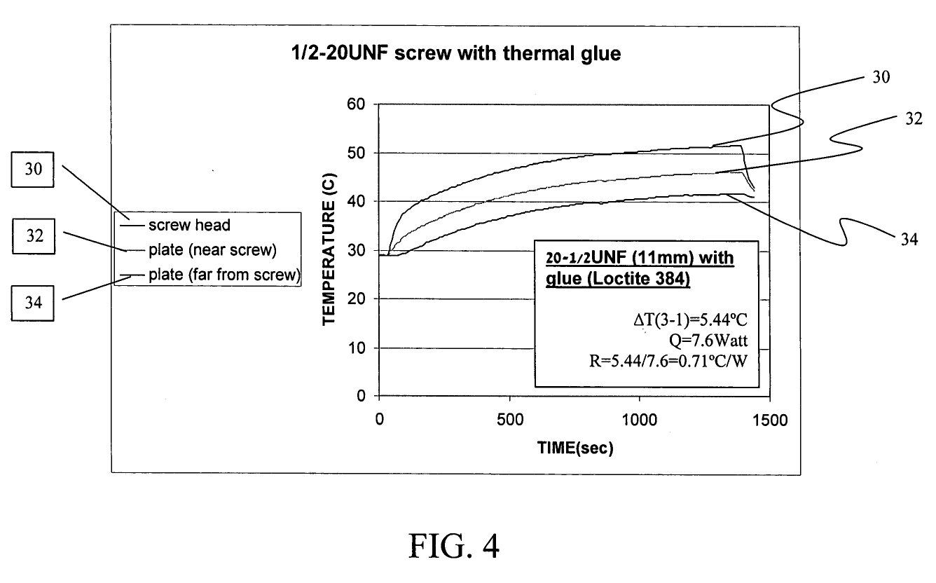

As seen in FIG. 4, with the same size screw as the test of FIG. 3 and the use of the thermally-conductive adhesive Loctite 384® as the thermally-conductive filler, the temperatures of the cold plate both near to 32 and removed from 34 the attachment opening stayed within approximately 10° C. of the temperature 30 of the extension segment.

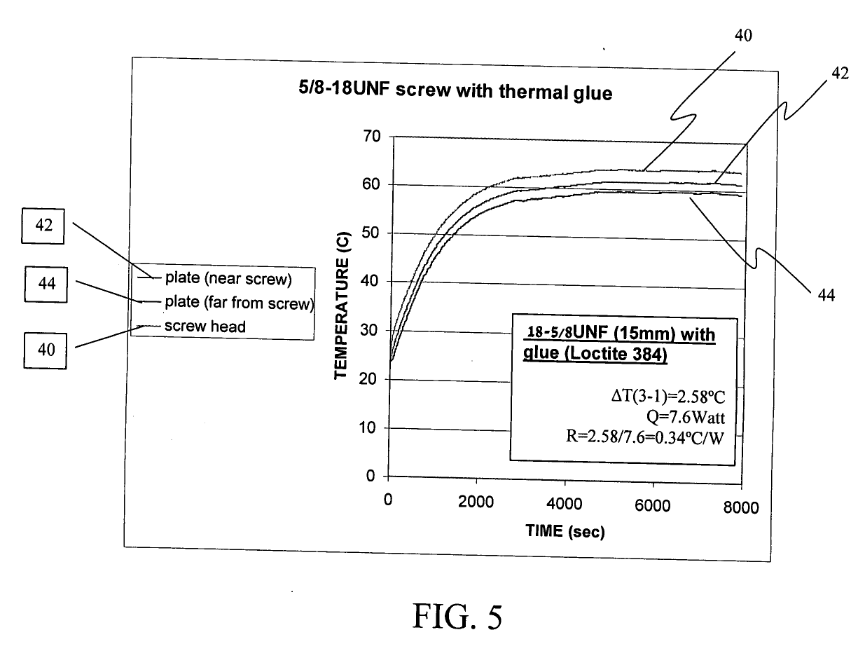

The test illustrated in FIG. 5 used a ⅝-18 UNF screw that was fixedly attached to the cold plate using the thermal adhesive Loctite 384°. The results of the test show that the temperatures of the cold plate both near to 42 and removed from 44 the attachment opening stay within approximately 5° C. of the temperature 40 of the extension segment. It should also be noted that the overall temperature attained during this test, levels off at a temperature approximately 10° C higher than that of the test using the smaller ½-20 UNF screw. This would seem to indicate a higher level of thermal conductivity provided by the larger ⅝-18 UNF screw, especially when fixed in the attachment opening with thermally-conductive adhesive.

Although the examples discussed above relate to a cooling system implemented with one attachment opening and one extension segment, it will be readily appreciated that the cooling system of the present invention may be implemented with multiple attachment openings and extension segments. It should be noted that in an application including multiple electrical components, the components need not all be the same, nor need they have coplanar contact surfaces. That is, the system of the present invention need not be limited to applications configured to cool multiple ICs all raised the same height off the PC board. Due to the adjustability of each individual extension segment, a system constructed and operable according to the teachings of the present invention may be configured to cool multiple components each having a contact surface at a different height from the supporting surface such as, but not limited to, a PC board. It should be further noted that the system of the present invention may be implemented in association with components that are mounted horizontally, vertically or at substantially any angle. Further, the system may be mounted above or below the components with which the system is associated. The extension segments may extend from the plane of the cold plate in either direction. A system configured with extension segments extending from the cold plate in more than one direction so as to cool components located on different sides of the cold plate are within the scope of the present invention.

It will also be appreciated that implementation of the principles of the present invention in association with any embodiment of a heat dissipation element that includes active cooling of the element, such as but not limited to, water jackets and refrigeration units, is within the scope of the present invention.

It will be appreciated that the above descriptions are intended only to serve as examples, and that many other embodiments are possible within the spirit and the scope of the present invention.

1. A heat transfer system for cooling electrical components mounted on a mounting surface, the system comprising:
(a) a heat dissipation element configured with at least one attachment opening, said attachment opening configured as a through bore;
(b) a thermally-conductive extension segment inserted through, and in contact with at least one peripheral wall of, each said attachment opening and extending toward the electrical component, wherein an extension length of said extension segment toward the electrical component is variable so as to facilitate positioning of a contact face of said extension segment in relation to a contact surface of the electrical component; and
(c) an elastically compressible thermally-conductive shock-absorbing pad deployed between, and contacting both, said contact face of said extension segment and said contact surface of the electrical component.

2. The system of claim 1, further comprising a thermally-conductive filler deployed in said attachment opening so as to enhance thermal conductivity between said heat dissipation element and said extension segment.

3. The system of claim 2, wherein said thermally-conductive filler includes a thermally-conductive adhesive.

4. The system of claim 1, wherein a distance between said contact face of said extension segment and said contact surface of the electrical component is in a range of between 0.1 mm-0.2 mm.

5. The system of claim 1, wherein at least a portion of said attachment opening is threaded.

6. The system of claim 5, wherein at least a portion of said extension segment is threaded so as to screw into said attachment opening, such that said extension length of said extension segment is varied by turning said extension segment.

7. A heat transfer method for cooling an electrical component mounted on a mounting surface, the method comprising:
(a) providing a heat dissipation element configured with at least one attachment opening, said attachment opening configured as a through bore;
(b) inserting a thermally-conductive extension segment through each of said at least one attachment opening so as to contact at least one peripheral wall of said opening and extending toward the electrical component;
(c) deploying an elastically compressible thermally-conductive shock-absorbing pad between a contact face of said extension segment and a contact surface of the electrical component; and
(d) varying an extension length of said extension segment toward the electrical component so as to facilitate positioning of a contact face of said extension segment in relation to a contact surface of the electrical component, said elastically compressible thermally-conductive shock-absorbing pad deployed there between, and in contact with both.

8. The method of claim 7, further comprising deploying a thermally-conductive filler in said attachment opening so as to enhance thermal conductivity between said extension segment and said heat dissipation element.

9. The method of claim 8, wherein said thermally-conductive filler is implemented as a thermally-conductive adhesive.

10. The method of claim 7, further comprising varying said extension length of said extension segment such that a distance between said contact face of said extension segment and said contact surface of the electrical component is in a range of between 0.1 mm-0.2 mm.

11. The method of claim 7, wherein at least a portion of said attachment opening is implemented as a threaded opening.

12. The method of claim 11, wherein at least a portion of said extension segment is threaded so as to screw into said attachment opening.

13. The method of claim 12, wherein said varying of said extension length of said extension segment is accomplished by turning said extension segment.
